(19) United States
(12) Patent Application Publication
(10) Pub. No.: US 2007/0076470 A1
(43) Pub. Date: Apr. 5, 2007

(54) Magnetic Random Access Memory Device and Sensing Method Thereof

(75) Inventors: Chien-Teh Kuo, St. Paul, MN (US); James Chyi Lai, St. Paul, MN (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: NORTHERN LIGHTS SEMICONDUCTOR CORP., St. Paul, MN (US)

(21) Appl. No.: 11/530,714

(22) Filed: Sep. 11, 2006

Related U.S. Application Data
(60) Provisional application No. 60/716,680, filed on Sep. 13, 2005.

(51) Int. Cl. G11C 11/00

(52) U.S. Cl. 365/158

(57) ABSTRACT

A magnetic random access memory (MRAM) device includes sense lines, a selector, a reading circuit and a writing circuit. Each sense line is coupled to one or more MRAM cells. The selector is used to select one of the sense lines to allow a read or write operation. The reading circuit is coupled to the sense lines and provides a first sense current to the selected sense line during the read operation. The writing circuit is coupled to the sense lines and provides a second sense current to the selected sense line during the write operation.

### CROSS-REFERENCE TO RELATED APPLICATION

This application claims the priority benefit of U.S. Provisional Application Ser. No. 60/716,680, filed Sep. 13, 2005, the full disclosures of which are incorporated herein by reference.

### BACKGROUND

1. Field of Invention

The present invention relates to static information storage and retrieval. More particularly, the present invention relates to systems using magnetic random access memory (MRAM).

2. Description of Related Art

Magnetic random access memory (MRAM) is a non-volatile computer memory (NVRAM) technology, which has been in development since the 1990s. Continued increases in density of existing memory technologies, notably Flash RAM and DRAM kept MRAM in a niche role in the market, but its proponents believe that the advantages are so overwhelming that MRAM will eventually become dominant.

Unlike conventional RAM chip technologies, data is not stored as electric charge or current flows, but by magnetic storage elements. The elements are formed from two ferromagnetic plates, each of which can hold a magnetic field, separated by a thin insulating layer. One of the two plates is a permanent magnet set to a particular polarity, and the other's field will change to match that of an external field. A memory device is built from a grid of such “cells”.

FIG. 1 illustrates a conventional MRAM array 110 having MRAM cells 112 located at cross points of word lines 114 and sense lines 116. Reading is accomplished by measuring the electrical resistance of the cell 112. Each sense line 116 in the memory array 110 is connected to a switch 130, and each switch 130 is connected to an input of a sense amplifier (not shown). The binary state, or “bit,” of a selected memory cell 112 is read by applying a 10 reading voltage to the word line 114 of the selected memory cell 112 while the sense line 116 crossing the memory cell 112 is connected to the input of the sense amplifier. The switch 130 connecting the selected sense line 116 to the sense amplifier is alternately opened and closed to read the selected memory cell 112. By measuring the resulting current, the resistance inside any particular cell can be determined, and from this the polarity of the writable plate. Typically if the two plates have the same polarity this is considered to mean “0”, while if the two plates are of opposite polarity the resistance will be higher and this means “1”.

Data is written to the cells by applying a writing voltage to the cell. Similarly, each of the sense lines 116 in the memory array 110 is connected to another switch 140, and each switch 140 is connected to a power source. A selected cell is written by applying a writing voltage to the word line 114 of the selected cell 112 while the switch 140 connecting the selected sense line 116 to the power source is alternately opened and closed to write the selected memory cell 112.

As stated above, each sense line, conventionally, requires two transistors 130 and 140 to implement reliable read and write operations. However, the transistors 130 and 140 of all sense lines occupy a large space, which is unpleasant in a modern design.

For the forgoing reasons, there is a need for a method and apparatus to reduce the memory size and increase the density of the memory.

### SUMMARY

According to one embodiment of the present invention, a magnetic random access memory (MRAM) device includes sense lines, a selector, a reading circuit and a writing circuit. Each sense line is coupled to at least one MRAM cell. The selector is used to select one of the sense lines to allow a read or write operation. The reading circuit is coupled to the sense lines and provides a first sense current to the selected sense line during the read operation. The writing circuit is coupled to the sense lines and provides a second sense current to the selected sense line during the write operation.

According to another embodiment of the present invention, a method for sensing an MRAM device includes the following steps: First, a sense line is selected from an MRAM array to allow a read or write operation. During the read operation, a first sense current is provided to the selected sense line. During the write operation, the first sense current and a second current are provided to the selected sense line simultaneously.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic view of a conventional magnetic random access memory (MRAM) array;

FIG. 2 is a schematic view of an MRAM device according to one embodiment of this invention;

FIG. 3 shows one embodiment of a switch coupled to the reading circuit 230 shown in FIG. 2; and

FIG. 4 shows another embodiment of a switch coupled to the writing circuit 240 shown in FIG. 2.

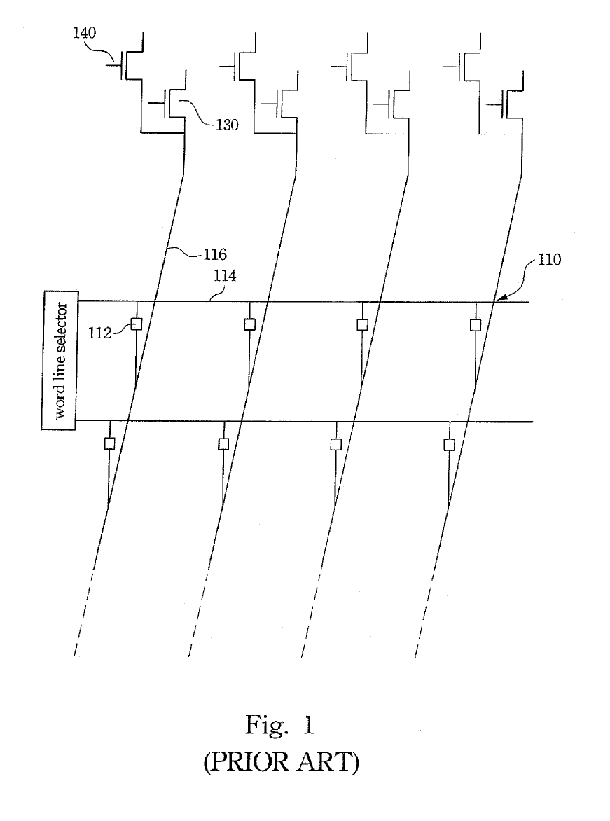

### DESCRIPTION OF THE PREFERRED EMBODIMENTS

Reference will now be made in detail to the present embodiments of the invention, examples of which are illustrated in the accompanying drawings. Wherever possible, the same reference numbers are used in the drawings and the description to refer to the same or like parts.

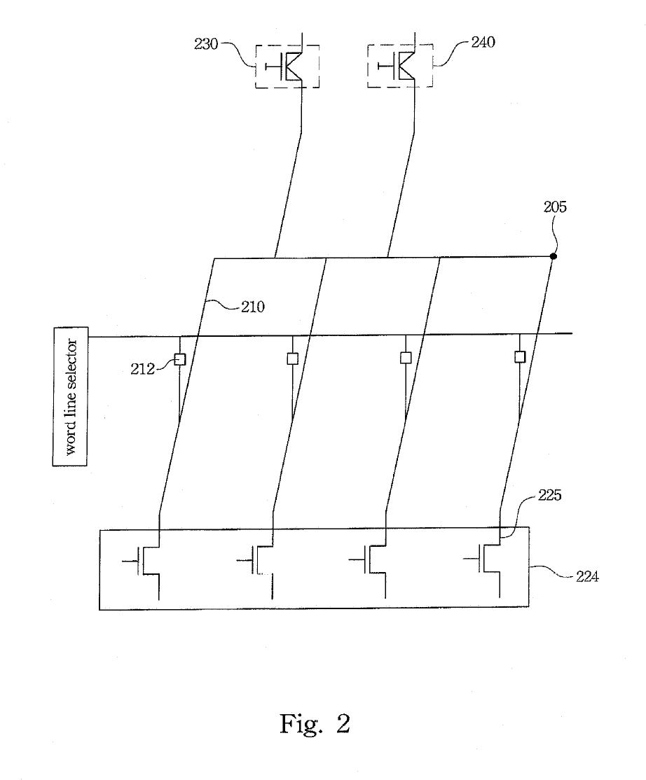

Refer to FIG. 2. FIG. 2 is a schematic view of a magnetic random access memory (MRAM) device according to one embodiment of this invention. As shown in FIG. 2, an MRAM device includes plural sense lines 210, a selector 224, a reading circuit 230 and a writing circuit 240. Each sense line 210 is coupled to at least one MRAM cell 212. The selector 224 is used to select one of the sense lines 210 to allow a read or write operation. The reading circuit 230 is coupled to the sense lines 210 and provides a first sense current to the selected sense line during the read operation. The writing circuit 240 is coupled to the sense lines 210 and provides a second sense current to the selected sense line during the write operation. The reading circuit 230 and the writing circuit 240 may comprise, for example, one or more transistors.

Compared with the conventional design, only the reading circuit 230 and the writing circuit 240 are coupled to the top end of the sense lines 210. Specifically, the reading circuit 230 and the writing circuit 240 are shared by the sense lines, yet each sense line has its own reading circuit and writing circuit in the conventional design. Therefore, the present embodiment allows a significant elimination of layout space compared with the conventional design, and hence the density of the memory can be increased.

Particularly, the reading circuit 230 may further provide the first sense current to the selected sense line during the write operation. This means the reading circuit 230 is activated during the read operation or during the write operation, and the writing circuit 240 is activated only during the write operation. Compared with the conventional design, which the first sense current and the second sense current are provided for the read operation and the write operation individually, the layout of the memory can be significantly smaller and easier to create because control circuits are reduced.

The reading circuit 230 and/or the writing circuit 240 may be mirrored from one or more bandgap circuits. Since a bandgap circuit has the characteristic of high stability against temperature and voltage variations, the bandgap circuit can be utilized to generate a constant voltage or current. Accordingly, the reading circuit 230 and the writing circuit 240, mirrored from the bandgap circuit(s), can provide a stable current as well.

Furthermore, the selector 224 may include a plurality of transistors 225 coupled to the MRAM cells 212 in series. Specifically, node 205 may be connected to an input of a sense amplifier (not shown). Assuming that a specific word line has supplied a reading voltage, the transistors 225 of the selector 224 connecting the sense lines 210 is alternately opened and closed to select the sense lines 210, and the reading circuit 230 provides the first sense current to the selected sense line during the read operation. By measuring the resulting current through the node 205, the resistance inside any particular cell can be determined, and from this the polarity of the writable plate.

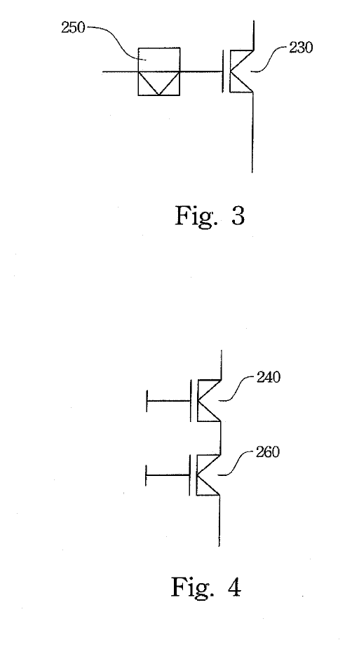

Because the MRAM device may has a plurality of MRAM arrays, and each MRAM array has an individual reading and writing circuit, there may be at least one switch coupled to the reading circuit and/or the writing circuit to determine which array is activated. As shown in FIG. 3, the switch may be a transmission gate 250 coupled to the reading circuit 230 (and/or the writing circuit). Alternatively, the switch may also be a P type channel metal oxide semiconductor (PMOS) 260 coupled to the writing circuit 240 (and/or the reading circuit) as shown in FIG. 4.

Specifically, a processor controls both the reading circuit and the writing circuit. If the reading circuit and the writing circuit of each MRAM array are independently controlled by the processor, the reading circuits and the writing circuits will occupy a large amount of pins on the processor. According to this embodiment, the processor can output a common signal to the MRAM arrays, and the switch will determine which MRAM array is activated. This saves the processor a lot of pins.

According to another embodiment of the present invention, a method for sensing an MRAM device includes the following steps: First, a sense line is selected from an MRAM array to allow a read or write operation. During the read operation, a first sense current is provided to the selected sense line. During the write operation, the first sense current and a second current are provided to the selected sense line simultaneously.

Although the present invention has been described in considerable detail with reference to certain embodiments thereof, other embodiments are possible. For example, both the reading circuit and the writing circuit may be PMOS, and the transistors of the selector may be N type channel metal oxide semiconductors (NMOS). Alternatively, the reading circuit and the writing circuit may also be NMOS and connected to a ground as current sink devices, and the transistors of the selector may be PMOS and connected to a power source. Therefore, their spirit and scope of the appended claims should no be limited to the description of the embodiments container herein.

In conclusion, the present invention has the following advantages:

(1) by making a working circuit and a reading circuit shared by plural sense lines, the size of the memory can be reduced and the density of the memory can be increased as well; and

(2) The layout of the memory is smaller and easier to create because of a reduced circuitry requirement.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A magnetic random access memory (MRAM) device comprising:
a plurality of sense lines each coupled to at least one MRAM cell;
a selector for selecting one of the sense lines to allow a read or write operation;
a reading circuit coupled to the sense lines and providing a first sense current to the selected sense line during the read operation; and
a writing circuit coupled to the sense lines and providing a second sense current to the selected sense line during the write operation.

2. The MRAM device of claim 1, wherein the reading circuit provides the first sense current to the selected sense line during the write operation.

3. The MRAM device of claim 1, wherein the reading circuit is mirrored from a bandgap circuit.

4. The MRAM device of claim 1, wherein the writing circuit is mirrored from a bandgap circuit.

5. The MRAM device of claim 1, wherein the selector comprises a plurality of transistors coupled to the MRAM cells in series.

6. The MRAM device of claim 1, further comprising a switch for switching the reading circuit.

7. The MRAM device of claim 1, further comprising a switch for switching the writing circuit.

8. A method for sensing a magnetic random access memory (MRAM) device comprising the steps of:
selecting a sense line from an MRAM array to allow a read or write operation;
providing a first sense current to the selected sense line during the read operation; and
providing the first sense current and a second sense current to the selected sense line during the write operation.
